(19) United States
(12) Patent Application Publication
(10) Pub. No.: US 2026/0239785 A1
(43) Pub. Date: Aug. 13, 2026

(54) LIGHT EMITTING DEVICE WITH TUNED BARRIER

(71) Applicant: LUMILEDS LLC, San Jose, CA (US)

(72) Inventors: Jeff DiMaria, Scotts Valley, CA (US); Yu-Chen Shen, Sunnyvale, CA (US); Grigoriy Basin, San Francisco, CA (US); Antonio Lopez-Julia, Vaals (NL); Marcel Rene Bohmer, Eindhoven (NL); Florent Monestier, Kerkrade (NL); Wouter Soer, Eindhoven (NL)

(73) Assignee: LUMILEDS LLC, San Jose, CA (US)

(21) Appl. No.: 19/051,428

(22) Filed: Feb. 12, 2025

(51) Int. Cl. H10H 20/856; H10H 20/851; H10H 20/852

(52) U.S. Cl. CPC H10H 20/856; H10H 20/8514; H10H 20/852

(57) ABSTRACT

A light source including an LED may be tuned to increase or decrease color uniformity throughout the device, such as at an edge of the light source, and/or improve contrast with less lumen loss. Tuning may include spectral tuning such as modification of the optical barrier and/or side coat surrounding the LED. The modification may include one or more of a dye, scattering particles, or luminescent material. The spectral tuning may increase output of light of a certain wavelength while decreasing output of light of another wavelength, due to increased reflection or emission of the former and increased absorption of the latter.

### FIELD OF THE INVENTION

The invention relates generally to barriers, specifically tuned barriers for LED light sources.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths. LEDs may be combined with one or more wavelength converting materials (generally referred to herein as “phosphors”) that absorb light emitted by the LED and in response emit light of a longer wavelength.

Inorganic LEDs and phosphor converted LEDs may be used to create different types of displays including, for example, augmented-reality (AR) displays, virtual-reality (VR) displays, and mixed-reality (MR) displays.

LEDs may serve as pixels in adaptive automotive forward lighting modules. These modules have requirements on pixel-to-pixel crosstalk, luminance cutoff, and optical efficiency. Pixel-to-pixel crosstalk is undesirable and is typically reduced by increasing spacing between light emitting surfaces (LES). However, increasing spacing results in a wide dark gap between pixels that can be seen on the roadway. In order to reduce this dark gap while maintaining low pixel-to-pixel crosstalk, optically absorbing material between emitters have been proposed. Existing concepts for optical barriers material in automotive forward lighting applications that require high contrast and low crosstalk between pixels cover barrier materials that absorb light uniformly across the visible spectrum which have a black appearance. In phosphor converted systems or systems with multiple light emitters of different colors existing barriers may cause issues. For example, typical phosphor converted LEDs have variation of the color over source that becomes increasingly saturated toward the edge of the phosphor emitter (i.e. more yellow, less blue). This color variation shows up as an undesirable artifact in applications where the source is projected, such as in automotive forward lighting.

### SUMMARY

Embodiments of this invention improves upon characteristics of the optical absorber and/or side coat materials to improve color over source artifacts in light emitting devices. For example, embodiments of the invention overcome the above stated disadvantages described in the Background section by utilizing a barrier with spectral response that varies by wavelength in order to improve the reflectivity, absorption, and/or emission of certain wavelengths of light at the boundary and make the color profile across the light emitting surface more uniform or less uniform, as desired.

For example, a non-black and/or colored optical barrier may more readily absorb and/or reflect light at certain wavelengths relative to other wavelengths. This advantageously improves the color uniformity in optical systems where high contrast between source pixels and high color uniformity across the entire array are required, such as sources used in automotive forward lighting projector optics. Alternatively or additionally, a luminescent material may be included in the optical barrier to improve uniformity or non-uniformity of light emission. If only light of selected wavelengths are absorbed by the barrier rather than light of all wavelengths, the lumen loss that may inherently occur upon introduction of light absorbing materials will be reduced.

For example, a black or grey optical barrier with scattering particles may improve contrast in a light emitting device while minimizing or lowering the lumen loss within the device.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1A schematically illustrates a cross-sectional view of a light source with an LED and a phosphor, where the optical barrier absorbs light emitted by the phosphor while reflecting light of the LED to increase color uniformity at the edge. FIG. 1B schematically illustrates a plan view of the device depicted in FIG. 1A.

FIG. 2A illustrates the case where the barrier is in direct contact with the LED. FIG. 2B schematically illustrates a plan view of the device depicted in FIG. 2A.

FIG. 3 schematically illustrates a cross-sectional view of a light source with an LED and a phosphor, where the optical barrier absorbs light emitted by the LED while reflecting light of the phosphor to increase color uniformity at the edge.

FIG. 4 schematically illustrates a cross-sectional view of a light source with an LED and a phosphor, where the optical barrier absorbs light emitted by the LED and emits light of a different wavelength.

FIG. 5 schematically illustrates a cross-sectional view of a light source with an LED and a phosphor, where there is a side coat without an optical barrier and the light source does not include a separate substrate.

FIG. 6A schematically illustrates a cross-sectional view of an array of direct emitting LEDs with an optical barrier that absorbs light from one of the LEDs while reflecting light from the other LED. FIG. 6B schematically illustrates a plan view of the device depicted in FIG. 6A.

FIG. 7 schematically illustrates a cross-sectional view of an array with the optical barriers being in direct contact with the LEDs.

FIG. 8 schematically illustrates a cross-sectional view of an array of direct emitting LEDs with a scattering side coat at the LED level and an optical barrier at the wavelength converting layer level.

FIG. 9 shows a graph of results of luminous flux versus contrast of an LED array as a function of blue pigment concentration for the case where the barrier is in direct contact with the LED. It also includes an example of a 20 μm thick black barrier in the middle of a 50 μm gap between LEDs.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

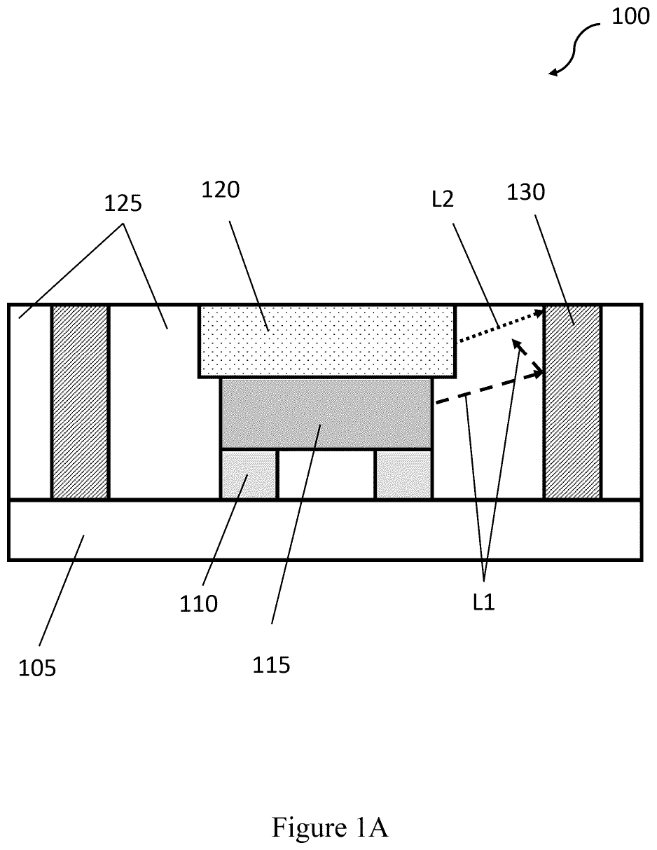

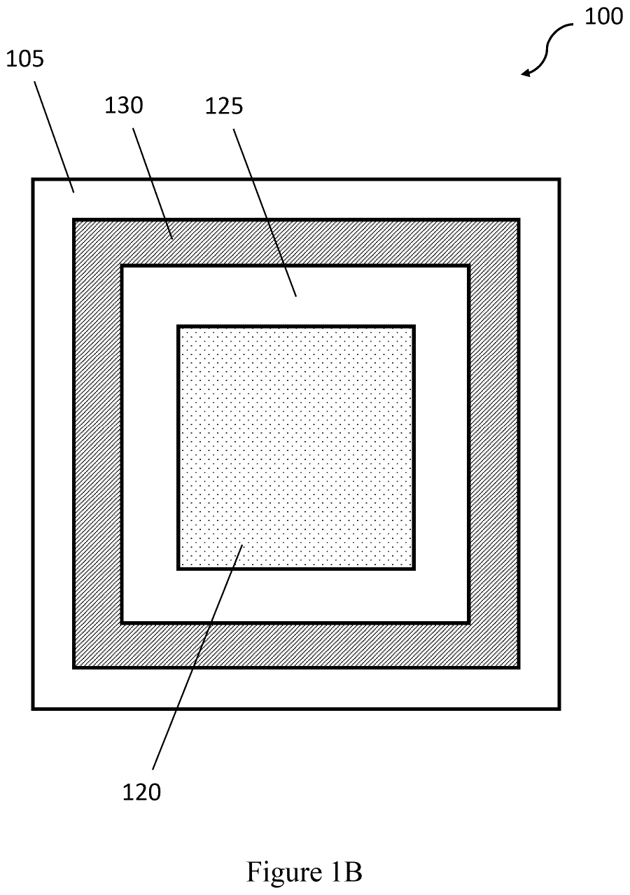

According to embodiments of the instant invention, FIG. 1A illustrates a light source 100 with a light emitting diode (LED) 115, a wavelength converting layer 120 disposed on the LED 115, and an optical barrier 130. The LED 115 may be disposed on a substrate 105 via contacts 110. The substrate 105 may be formed of any suitable material and may optionally comprise CMOS circuitry for driving the LED 115. The LED 115 and wavelength converting layer 120 may be disposed to be surrounded by side coat 125 and the optical barrier 130. The side coat 125 may itself be surrounded by the optical barrier 130, and may include a material such as transparent silicone and particles in the silicone such as TiOₓ (e.g., TiO₂), or aluminum or gold nanoparticles, which improve scattering. The scattering particles may be included at from 0-20 volume % of the side coat 125, such as from 5-10 volume %. The optical barrier 130 may be spaced apart or in direct contact with one or both of the LED 115 and the wavelength converting layer 120, although it may be in direct contact with one or either if the side coat 125 is omitted. The LED 115 emits a light of a first wavelength (e.g., maximum wavelength or wavelength range). The wavelength converting layer 120 may include a luminescent material (i.e., phosphor), which absorbs light of the first wavelength and emits light of a second wavelength that may be different from the first wavelength. The wavelength converting layer 120 may include a binder and phosphor particles or quantum dots embedded in the binder. The wavelength converting layer 120 may be ceramic phosphor. In an example, LED 115 may emit blue light while the wavelength converting layer 120 may absorb the blue light and emit yellow light in response. Of course, the emitted and/or absorbed colors of respectively the LED 115 and wavelength converting layer 120 may be any visible color, such as red, blue, green, yellow, or it may be infrared or ultraviolet. The wavelength converting layer 120 may be in direct contact with or spaced apart from the LED 115. In either case, the wavelength converting layer 120 may be in an optical path of the LED 115 such that it absorbs a majority of the light of the first wavelength, although this is not necessary and it may absorb a portion less than a majority of the light of the first wavelength.

The LED 115 and the wavelength converting layer 120 may emit light from its light emitting surface (opposite from and farthest from the substrate 105, for example) and/or its sidewalls facing the optical barrier 130 which is incident on the optical barrier 130. This is illustrated in FIG. 1A where LED 115 emits light L1 of a first wavelength and wavelength converting layer 120 emits light L2 of a second wavelength after absorbing light L1. LED 115 emits light L1 from its sidewall incident on optical barrier 130 and wavelength converting layer 120 emits light L2 from its sidewall incident on the same optical barrier 130

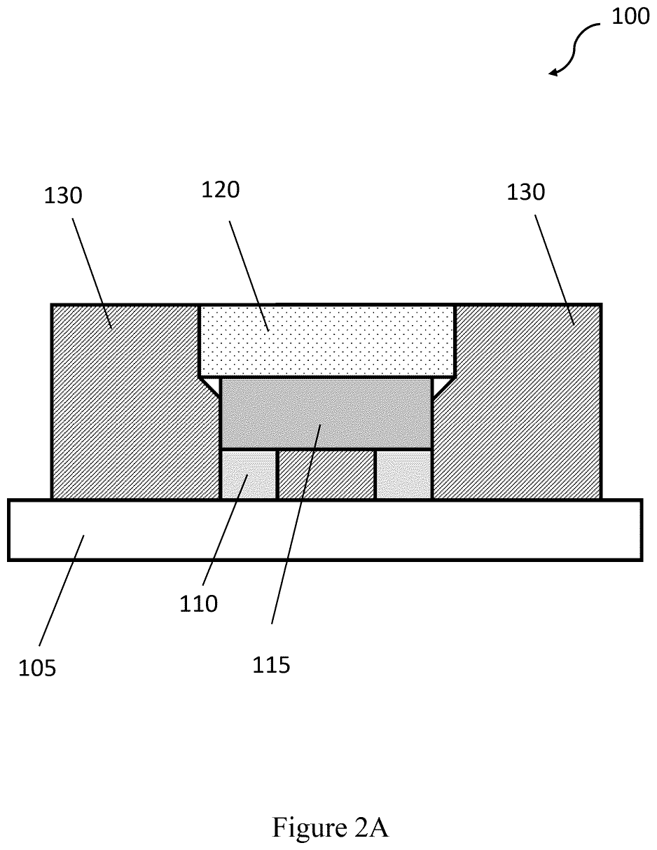

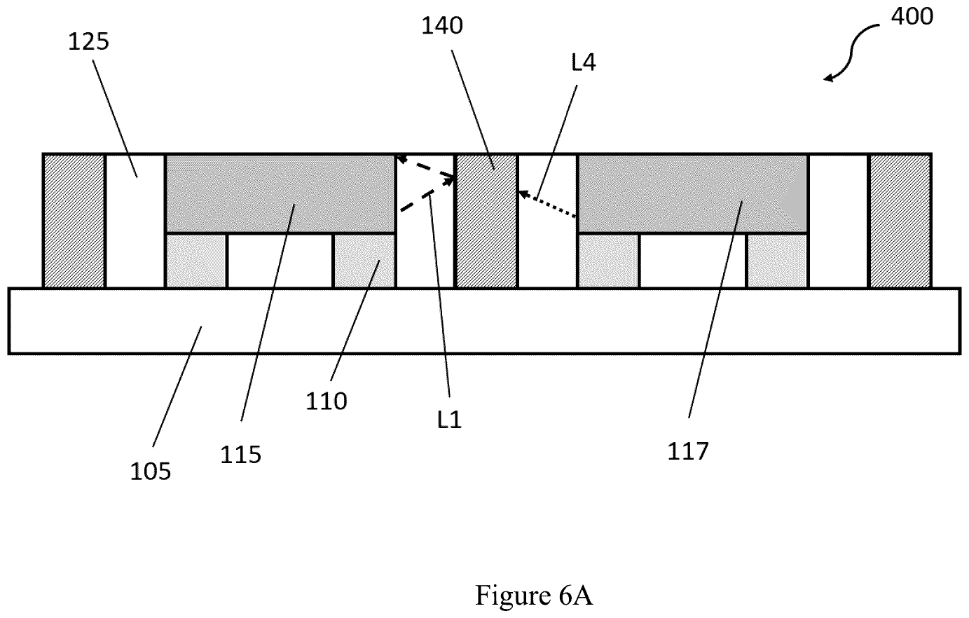

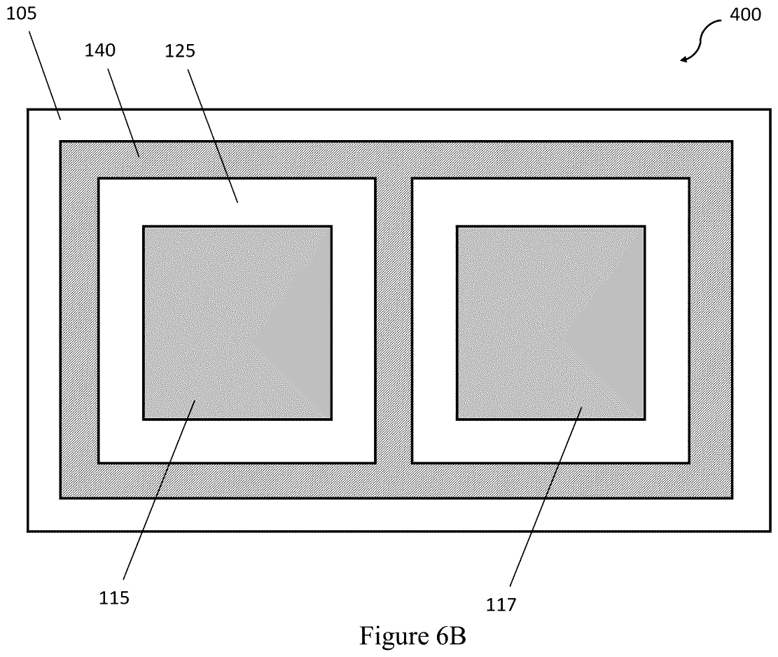

The optical barrier 130 can be made by a variety of methods. One method is to create a thin trench in the side coat via a saw blade, dispense the barrier material (e.g., silicone), planarize the excess barrier material, and etch back the planarized excess barrier material. The optical barrier 130 may have a width from 10-50 microns, such as from 15-30 microns, such as 20 microns. The optical barrier 130 can be spectrally tuned in a variety of ways: through optical absorption (the optical barrier 130 being polymer and dye or pigment), through varying particle size via Rayleigh scattering (the optical barrier 130 being polymer and metal or dielectric micro/nanoparticles, such as aluminum or gold nanoparticles with radius 50-200 microns) and/or via up or down-conversion (the optical barrier 130 being a binder and at least one luminescent material/particle, e.g. quantum dots, phosphor, where the binder is a same or different material from a binder of the side coat 125). When the optical barrier 130 comprises pigment the vol % of the pigment may be from above 0.1-2 vol %, such as from 0.5-1.5 vol %, such as from 1.0-1.25 vol % of the optical barrier 130. Another way to characterize any pigment present in the optical barrier 130 is that it may be 0.1-5 weight % (such as 1-4 weight %, such as 2-3 weight %) with respect to one or more scattering particles (e.g., TiOₓ) in either the optical barrier 130 alone or the optical barrier 130 and side coat 125 together. Any luminescent material present may be a different or same as that included in the wavelength converting layer 120. Alternatively, the optical barrier 130 may include no luminescent materials. In embodiments of the invention, where the optical barrier 130 has a high level of scattering and a defined but limited absorption, the optical barrier 130 may be placed in direct contact with the LED 115 and/or the wavelength converting layer 120 (and/or contact 110), leading to less processing steps. In this case, the side coat 125 may be omitted. This is shown in FIGS. 2A, 2B, and 6.

Suitable materials to include in the optical barrier 130 include pigments that selectively absorb certain wavelengths. For example, reflection of blue light can be established with a blue pigment, preferably an inorganic blue pigment, as inorganic pigments are in general more temperature and light-stable than organic pigments. Examples of inorganic pigments are cobalt-aluminate (CoAl₂O₄) and YInMn-blue (YIn₁₋ₓ₎Mnₓ); blue organic pigment like Cu-phtalocyanine are also fairly stable and may be used as the absorption spectra of organic pigments are often more selective than those of inorganic pigments. Further examples of pigments are particles comprising TiO₂, SiO₂ and borosilicate, that strongly scatters blue light without showing any absorption from 400-800 nm. Green or red pigments, or pigments of any other color, may also or alternatively be used. The pigments may be white or black or a non-white, non-black pigment.

The side coat 125 can also be spectrally tuned via one or more of the materials described for the optical barrier 130 above, to further improve color uniformity. For example, the side coat 125 may be dyed or pigmented, such as including the same dye or pigment as used in the optical barrier 130. The side coat 125 may also have the size distribution of its scattering particles (such as TiOₓ) be spectrally tuned so that they preferentially scatter one color of wavelength more than the other compared to non-spectrally tuned scattering particles. For example, the scattering particles can be spectrally tuned to scatter longer wavelength light more than shorter wavelength light. Alternatively or furthermore, the side coat 125 may include luminescent materials that may absorb one of light emitted from the LED 115 and/or the wavelength converting layer 120. The luminescent material may be a different one from that included in the wavelength converting layer 120, or a same material with a greater, lesser, or equal concentration within the side coat 125 compared to the luminescent material concentration in the binder of wavelength converting layer 120. That is, the luminescent material included in the side coat 125 may emit the same color as that included in the wavelength converting layer 120, or different colors. Alternatively, the side coat 125 may not include any luminescent materials. The side coat 125 may include a different binder material than the wavelength converting layer 120, or the same material. When the side coat 125 is spectrally tuned, the optical barrier 130 may be black instead of colored, or a spectrally tuned side coat 125 may be used in conjunction with a colored or otherwise spectrally tuned optical barrier 130 to even further affect color uniformity. The dye, pigment, and/or phosphor included in the side coat 125 may be in addition to the scattering particles such as TiOₓ already included in the side coat 125. When the side coat 125 includes one or more of the same material as the optical barrier 130 (whether that material is pigment, scattering particles, luminescent material, etc.) that material may be included in the side coat 125 in the same, greater, or lesser vol % or total weight % compared to that material in the optical barrier 130.

Some examples of luminescent materials useable in the side coat 125 and/or wavelength converting layer 120 include the following listed below.

Suitable green phosphors include, but are not limited to, aluminum garnet phosphors with the general formula (Lu_{1-x-y-a-b}YₓGd_{y})₃(Al_{1-z}Ga_{z})₅O₁₂:CeₐPr_{b} wherein 0<x<1, 0<y<1, 0<z≤0.1, 0<a≤0.2 and 0<b≤0.1, such as Lu₃Al₅O₁₂:Ce³⁺ and Y₃Al₅O₁₂:Ce³⁺, Lu_{3-x-y}M_{y}Al_{5-z}A_{z}O₁₂:Ceₓ where M=Y, Gd, Tb, Pr, Sm, Dy; A=Ga, Sc; and (0<x≤0.2); Ca_{3-x-y}M^{y}Sc_{2-z}A_{z}Si₃O₁₂:Ceₓ where M=Y, Lu; A=Mg, Ga; and (0<x≤0.2); Ba_{2-x-y}M_{y}SiO₄:Euₓ where M=Sr, Ca, Mg and (0<x≤0.2); Ba_{2-x-y-z}M_{y}K_{z}Si_{1-z}P_{z}O₄Euₓ where M=Sr, Ca, Mg and (0<x≤0.2); Sr₁₋ₓ−yM_{y}Al_{2-z}Si_{z}O_{4-z}N_{z}:Euₓ where M=Ba, Ca, Mg and (0<x≤0.2); M₁₋ₓSi₂O₂N₂:Euₓ where M=Sr, Ba, Ca, Mg and (0<x≤0.2); M₃₋ₓSi₆O₉N₄:Euₓ where M=Sr, Ba, Ca, Mg and (0<x≤0.2); M₃₋ₓSi₆O₁₂N₂:Euₓ where M=Sr, Ba, Ca, Mg and (0<x≤0.2); Sr_{1-x-y}M_{y}Ga_{2-z}Al_{z}S₄:Euₓ where M=Ba, Ca, Mg and (0<x≤0.2); Ca_{1-x-y-z}M_{z}S:CeₓA_{y} where M=Ba, Sr, Mg; A=K, Na, Li; and (0<x≤0.2); Sr_{1-x-z}M_{z}Al_{1+y}Si_{4×2-y}N_{7-y}O_{0.4+y}:Euₓ where M=Ba, Ca, Mg and (0<x≤0.2); Ca_{1-x-y-z}MySc₂O₄:CeₓA_{z} where M=Ba, Sr, Mg; A=K, Na, Li; and (0<x≤0.2); M_{x-z}Si_{6-y-2x}Al_{y+2x}O_{y}N_{8-y}:Eu_{z} where M=Ca, Sr, Mg and (0<x≤0.2); and Ca_{8-x-y}M_{y}MgSiO₄Cl₂:Euₓ where M=Sr, Ba and (0<x≤0.2).

Suitable examples of red phosphors include, but are not limited to, (Sr_{1-x-y}BaₓCa_{y})_{2-z}Si₅₋ₐAlₐN₈₋ₐOₐ:Eu_{z}²⁺ wherein 0≤a<5, 0<x≤1, 0≤y≤1, and 0<z≤1, such as Sr₂Si₅N₈:Eu²⁺, Ca_{1-x-z}M_{z}S:Euₓ where M=Ba, Sr, Mg, Mn and (0<x≤0.2); Ca_{1-x-y}M_{y}Si_{1-z}Al_{1+z}N_{3-z}O_{z}:Euₓ where M=Sr, Mg, Ce, Mn and (0<x≤0.2); Mg₄Ge₁₋ₓO₅F:Mnₓ where (0<x≤0.2); M₂₋ₓSi_{5-y}Al_{y}N_{8-y}O_{y}:Euₓ where M=Ba, Sr, Ca, Mg, Mn and (0<x≤0.2); Sr_{1-x-y}M_{y}Si_{4-z}Al_{1+z}N_{7-z}O_{z}:Euₓ where M=Ba, Ca, Mg, Mn and (0<x≤0.2); and Ca_{1-x-y}M_{y}SiN₂:Euₓ where M=Ba, Sr, Mg, Mn and (0<x≤0.2).

Suitable examples of cyan, yellow, and/or red emitting phosphors further include, but are not limited to, (Sr_{1-a-b}Ca_{b}Ba_{c})SiₓN_{y}O_{z}:Euₐ²⁺ (a=0.002−0.2, b=0.0−0.25, c=0.0−0.25, x=1.5−2.5, y=1.5−2.5, z=1.5−2.5) including, for example, SrSi₂N₂O₂:Eu²⁺; (Sr₁₋ᵤ₋ᵥ₋ₓMgᵤCaᵥBaₓ)(Ga_{2-y-z}Al_{y}In_{z}S₄):Eu²⁺ including, for example, SrGa₂S₄:Eu²⁺; Sr₁₋ₓBaₓSiO₄:Eu²⁺; and (Ca₁₋ₓSrₓ)S:Eu²⁺ wherein 0<x<1 including, for example, CaS:Eu²⁺ and SrS:Eu²⁺. Of course, phosphors of other colors, such as blue phosphors, may also be used.

In the example illustrated in FIG. 1A, optical barrier 130 absorbs and/or reflects light of different wavelength unequally, i.e., reflects light L1 more than light L2 and/or absorbs light L2 more than light L1. Light L1 or L2 may each be different colors of one of blue, red, green, cyan, yellow, magenta etc. For example, the optical barrier 130 may be colored blue so that it reflects blue light while absorbing yellow light, with the LED 115 emitting blue and the wavelength converting layer 120 emitting yellow in response to blue absorption. The optical barrier 130 may be more absorptive of light L2 than light L1 and more reflective of light L1 than light L2. For example, reflectance of light L1 may be quantified in the range of 80-100% (e.g., 90-95%) and absorptance of light L2 may be quantified in the range 90-100% (e.g., 90-95%). A light source with a configuration similar to the light source 100, where the wavelength converting layer 120 has a greater size/area than the LED 115, may have nonuniformity in color at the edges due to the size discrepancy. With the optical barrier 130, light L1 at or near the edge may be reflected by optical barrier 130 to be emitted by the light source 100, while light L2 at or near the edge may be absorbed so that less of light L2 is emitted at the edge compared to if the optical barrier 130 were not there. In this way color uniformity is achieved throughout the light source 100 and especially at the edges.

Alternatively, the optical barrier 130 may absorb and/or reflect light equally. For example, the optical barrier 130 may comprise a binder or filler, a black pigment, and a scattering particle that is or includes a different material from the black pigment such as TiOₓ. This type of barrier provides good contrast in the light emitting device while minimizing lumen lost. Alternatively, grey pigment or blue pigment may be used instead with the scattering particle.

According to embodiments of the invention, a light emitting device with the structure of FIG. 1A may include an LED 115 emitting blue light, a wavelength converting layer 120 converting incident LED blue light into red, and the pigment and/or red phosphor in the optical barrier 130 that absorbs blue light from the LED and/or converts it into red light. The blue light emitted by this LED is for example completely converted to red light. As the blue LED also emits blue light to the side, it is difficult to obtain a high color purity. Therefore a pigment can be added to the side coat containing strongly scattering high index particles like TiO₂ in a preferably low refractive index silicone which is the side coat 125 used that efficiently absorbs blue light. Inorganic pigments like iron oxide or zinc-ferrite are suitable for a phosphor converted red LED. Alternatively, a red emitting phosphor could be added, this should lead to less lumen loss.

FIG. 1B illustrates a top down view of the light source shown in FIG. 1A, which may be similar or a same as the top down view of light sources shown in other figures described below. The optical barrier 130 may fully horizontally surround the wavelength converting layer 120 and/or LED 115, where a horizontal direction extends along the plane of the page of FIG. 1B. In the case of the optical barrier 130 directly contacting the LED 115 and wavelength converting layer 120, the situation is simplified to that given in FIG. 2A, where only an optical barrier 130 is present around the LED without a side coat 125.

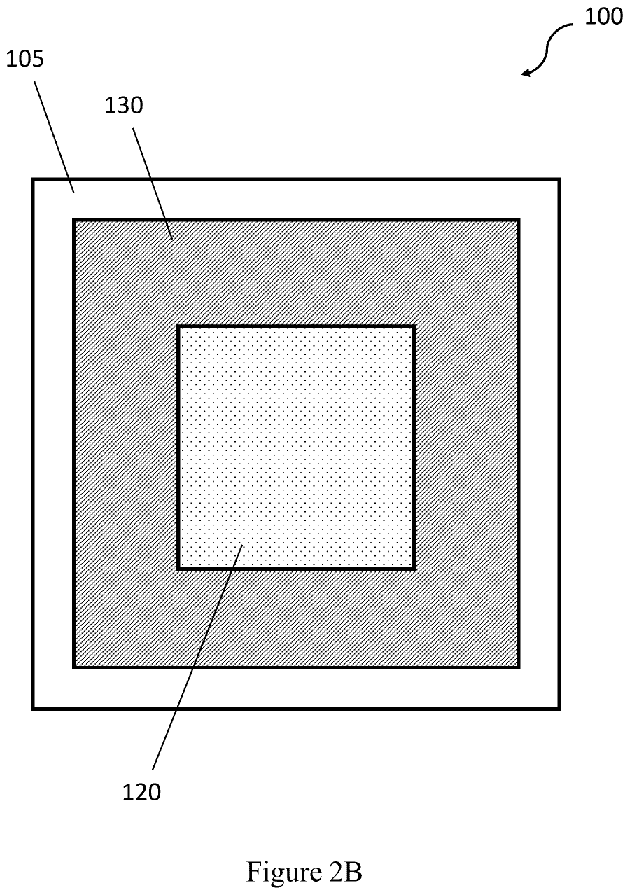

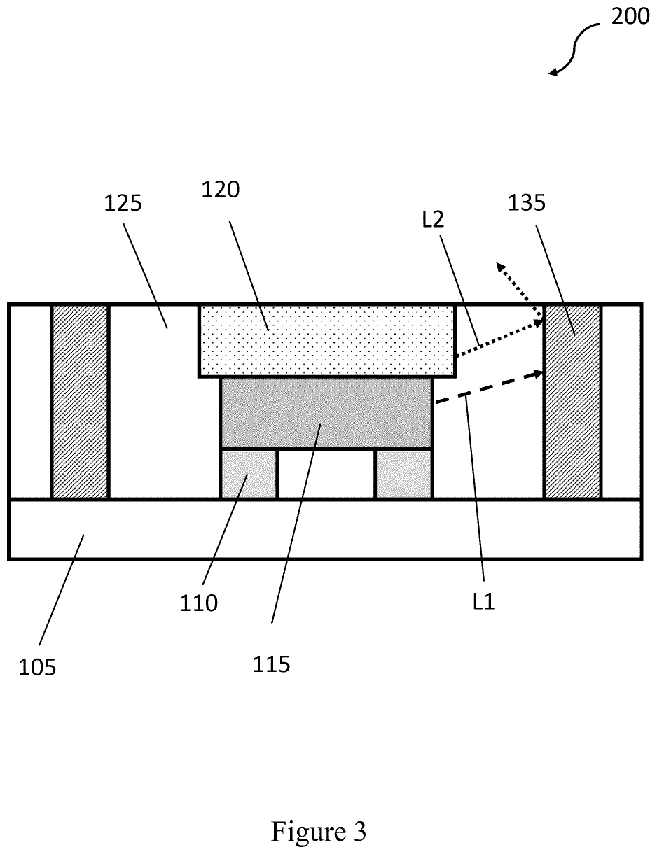

According to embodiments of the instant invention, FIG. 3 illustrates a light source 200 with an optical barrier 130 that absorbs light L1 emitted from the LED 115 while reflecting light L2 emitted from luminescent material of the wavelength converting layer 120. For example, the optical barrier 130 may be colored yellow so that it reflects yellow light while absorbing blue light, with the LED 115 emitting blue and the wavelength converting layer 120 emitting yellow in response to blue absorption. The optical barrier 130 of FIG. 3 may enhance the non-uniformity of the light emitted by the light source 200 so that more light L2 is emitted than light L1, particularly at the edges of light emission, for applications which prefer non-uniformity.

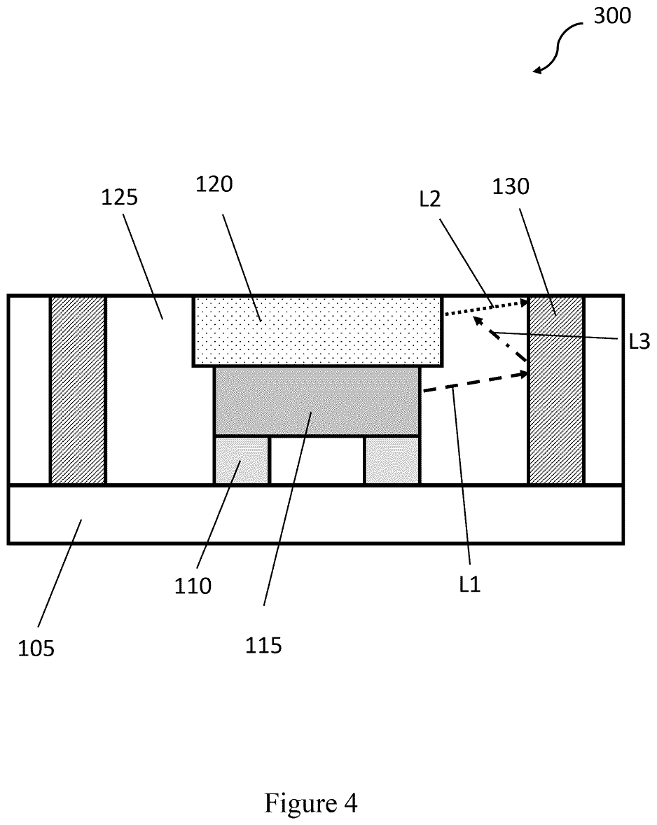

According to embodiments of the instant invention, FIG. 4 illustrates a light source 300 with an optical barrier 130 that absorbs light L1 emitted from the LED 115 while emitting light L3 in response to the absorption. Optical barrier 130 may include one or more luminescent materials and/or particles such as phosphor particles or quantum dots. At least one of the luminescent materials absorbs light L1 and emits light L3 in response. Light L3 may be light of a third wavelength the same as the second wavelength of light L2, or it may be a different wavelength compared to light L2. That is, the luminescent material in optical barrier 130 may up-convert or down-convert light L1, as desired. Although FIG. 4 shows that light L2 is absorbed by the optical barrier 130, light L2 may alternatively be reflected by optical barrier 130.

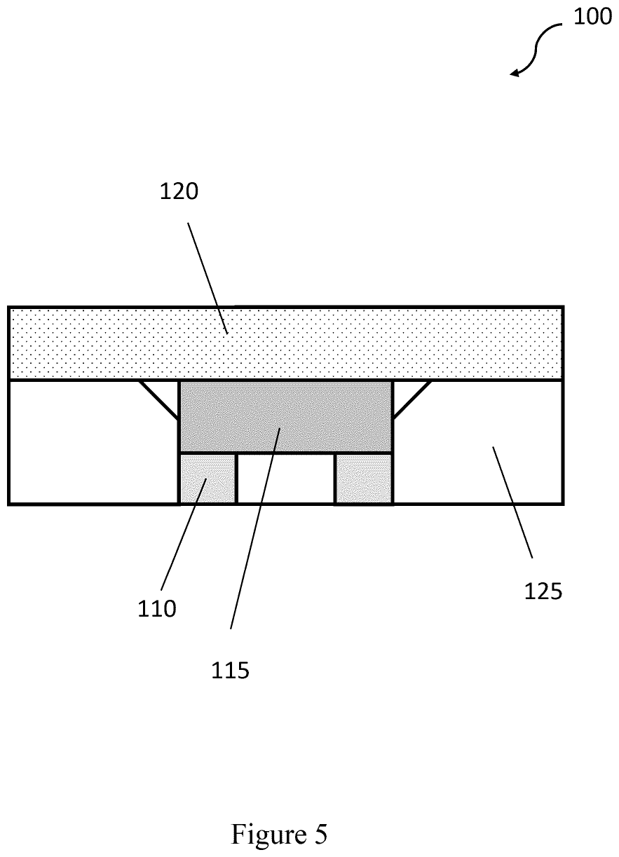

According to embodiments of the instant invention, FIG. 5 illustrates an individual LED light source with a side coat 125 that serves the purpose of an optical barrier 130. For example, the side coat 125 may include, as described above, scattering particles as well as spectral tuning as described above, e.g., pigments and/or phosphors. As a result, the light source may have no separate optical barrier 130. The light source may also have no separate substrate 105 in this embodiment.

According to embodiments of the instant invention, FIG. 6A illustrates a light emitting array 400 with a LED 115 that emits light L1 and a LED 117 that emits light L4 of a fourth wavelength that may be different than a first wavelength of light L1. The optical barrier 130 or a portion of it may be adjacent to both the LED 115 and the LED 117, i.e., disposed between LED 115 and LED 117. The optical barrier 130 may be spaced apart or in direct contact with one or both of the LED 115 and the LED 117. The optical barrier 130 may absorb light L4 while reflecting light L1. This is because in an array such as this one, LEDs of different colors may require relative brightness to be made more uniform. For example, the light emitting array 400 may have a low efficiency red pixel (LED 115) and an adjacent high efficiency green pixel (LED 117) with no intervening pixels therebetween, where crosstalk is not desired. In this situation the optical barrier 130 may be a red-reflecting, green-absorbing barrier can be employed to absorb green light emitted by the higher output pixel LED 117, and efficiently reflect red light emitted by the lower output pixel LED 115. This can reduce mismatch between driver conditions of the LEDs (red pixel driven at high current, green pixel driven at low current), which may lead to a driver circuit that is better optimized for both red and green drive conditions by having the system driven over a narrower range. The driver can be optimized over this narrower range and may have an overall system efficiency benefit.

FIG. 6B illustrates a top down view of the array shown in FIG. 6A. The optical barrier 130 may fully horizontally surround the LED 115 and LED 117, where a horizontal direction extends along the plane of the page of FIG. 6b. A part of the optical barrier 130 may be between the LED 115 and LED 117. Alternatively, the optical barrier 130 may only partially horizontally surround one or both of the LED 115 and 117, such as being disposed adjacent to only two or three sides of the LEDs 115 and 117 (e.g., extending fully adjacent to opposing sides of each LED without being adjacent to the two other sides).

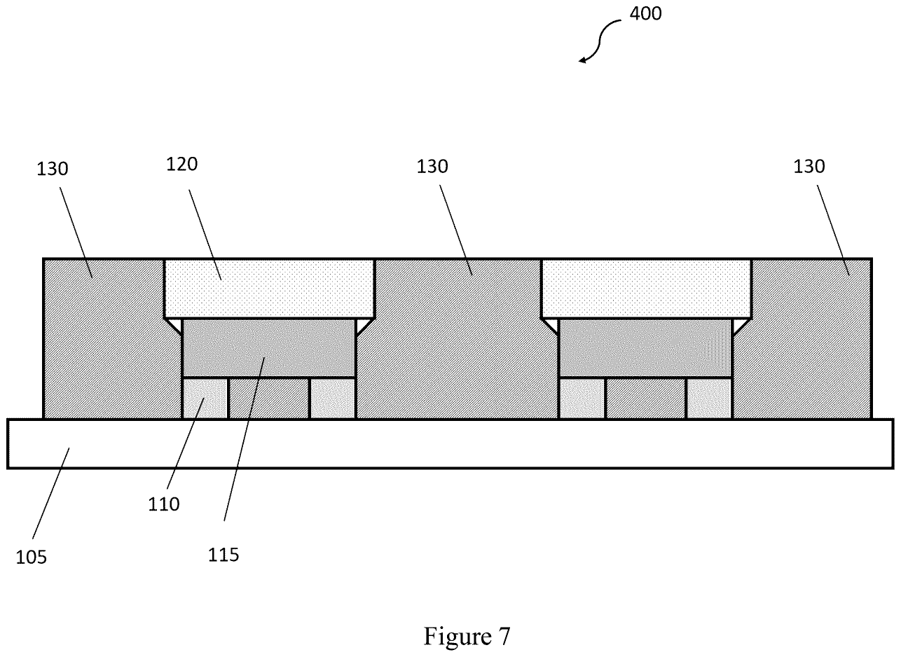

FIG. 7 shows an embodiment of the invention of an array with wavelength converting layers 120 and LEDs 115 in direct contact with the optical barrier 130. No side coat 125 is present in the array.

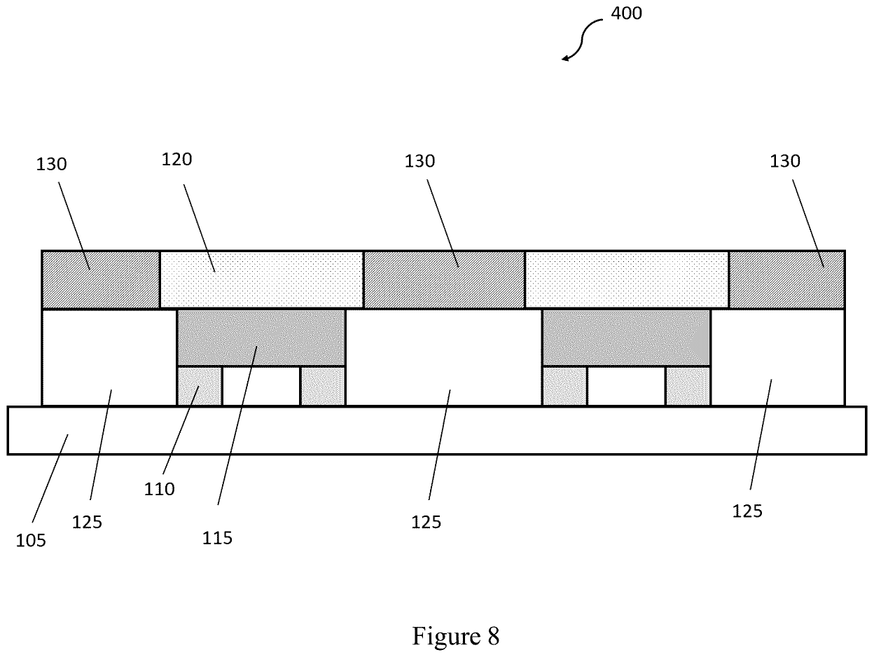

FIG. 8 shows the case where a side coat 125 serving as a scattering layer is first applied. The side coat 125 efficiently reflects, for example, blue light emitted to the sides by the die back into the LED. At the level of the conversion layer an optical barrier 130 is applied as a separate layer from the side coat 125. In the optical barrier 130 an absorber is introduced such that the light emitted to the sides does not reach the neighboring pixel. In case a blue pigment is used, blue light is reflected back in the wavelength conversion layer 120 as much as possible, while higher wavelengths emitted to the sides are completely or partially absorbed. In other words, the optical barrier 130 may fully or partially horizontally surround the wavelength converting layer 120 without even partially horizontally surrounding the LED 115, while the side coat 125 may fully or partially horizontally surround the LED 115 without even partially horizontally surrounding the wavelength converting layer 120. Put another way, the side coat 125 may extend in a vertical direction without reaching the vertical position of the wavelength converting layer 120. Although this is a more complex configuration for manufacturing compared to a homogeneous layers with a certain pigment concentration, it will lead to less lumen loss at certain contrast.

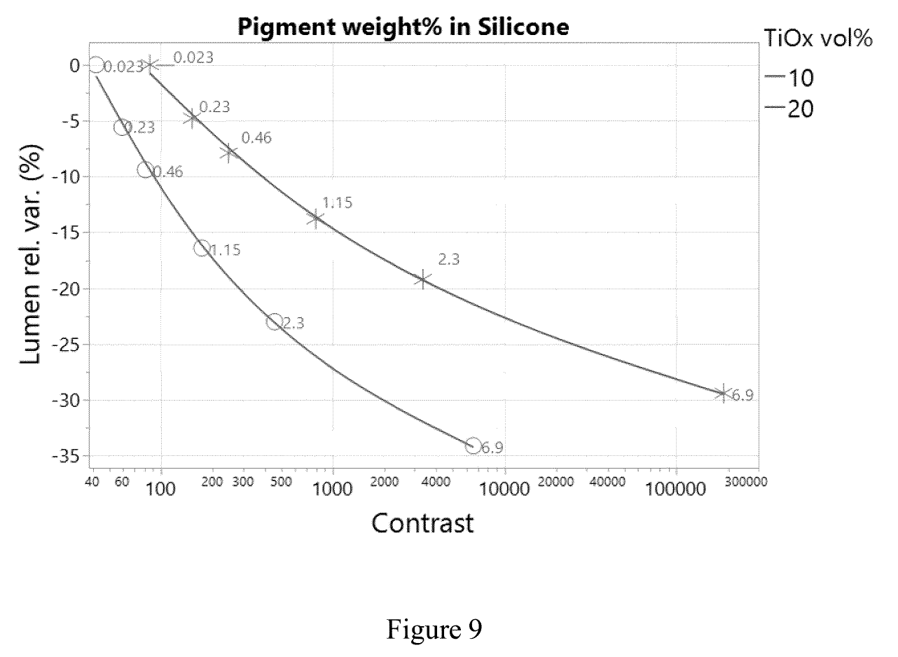

FIG. 9 is a graph that show results of calculations of a arrays with five LEDs with the center pixel switched off. In all calculations the LEDs are 1×1 mm, 50 μm apart and a silicone with refractive index 1.41 is used. The bottom line (starting leftmost) shows results of a blue pigment, YInMn-blue, concentration series added to a fixed TiO₂ concentration in silicone, in the case where the barrier width is equal to the LED spacing. It shows that the luminous flux decreases with increasing pigment concentration while the contrast increases. These results help to choose the amount of pigment needed to arrive at certain contrast, and quantify the concomitant lumen loss. For instance for a contrast of 150 between on and off neighbouring pixels a lumen loss of 10% is found. If in this configuration the blue pigment is replaced by a black pigment the lumen loss is 11% at a contrast of 150. Labels indicated in the chart are pigment concentration in weight percentage without TiOₓ (i.e assuming TiOₓ is not in). For a mixture of Silicone, pigment and TiOₓ, the wight percentage will have to be adapted accordingly to TiOₓ mass density. Contrast is defined for a 1×5 emitters row of 1 mm2 where the center pixel is switched off as the ratio of power emitted by 80% of light emitting area of the neighbor pixel (pixel 2 or 4) divided the power leaking into the center pixel off (pixel 3) over 80% of its light emitting area. Lumen rel. var is the Lumen variation relative to case without pigment. This characteristic number can also be compared with different configuration, for instance a 20 μm barrier in the middle of the 50 μm gap filled with a black pigment. The top line (ending rightmost) represents the results in case no additional scattering particles are present in the black barrier layer. The lumen loss at a contrast of 150 is slightly worse than for the homogeneous blue layer of blue pigment and scattering particles. However if the barrier is made with black pigment and scattering particles, the luminous flux loss is smaller, around 6% at a contrast of 150.

Embodiments of the invention may be used for any application that requires or desires high contrast (low crosstalk) between pixels, sharp optical cutoff (single or multi emitter), and high optical efficiency. These include, but are not limited to automotive forward lighting, direct-view displays/signage, projector displays, and camera flash.

This disclosure is illustrative and not limiting. Further modifications will be apparent to one skilled in the art in light of this disclosure and are intended to fall within the scope of the appended claims.

What is claimed is:

1. A light source comprising:
a light emitting structure configured to emit at least one of a light of a first wavelength and a light of a second wavelength that is different from the first wavelength;
an optical barrier disposed adjacent to the light emitting structure comprising a top surface, a bottom surface opposite the top surface, and side walls extending between the top surface and the bottom surface, wherein the optical barrier:
absorbs the light of the first wavelength; and
reflects or emits the light of the second wavelength.

2. The light source of claim 1, wherein the light emitting structure comprises a light emitting device arranged to emit one of the light of the first wavelength and the light of the second wavelength.

3. The light source of claim 2, wherein the light emitting structure comprises a wavelength converting layer disposed on the light emitting device and arranged to absorb one of the light of the first wavelength and the light of the second wavelength emitted by the light emitting device and in response emit an other of the light of the first wavelength and the light of the second wavelength.

4. The light source of claim 3, wherein the wavelength converting layer is arranged to absorb the light of the first wavelength and in response emits the light of the second wavelength.

5. The light source of claim 3, wherein the wavelength converting layer is arranged to absorb the light of the second wavelength and emits the light of the first wavelength.

6. The light source of claim 3, wherein the wavelength converting layer comprises a light emitting surface flush with the top surface of the optical barrier.

7. The light source of claim 2, wherein the light emitting device is arranged to emit the light of the first wavelength.

8. The light source of claim 2, wherein the light emitting device is arranged to emit the light of the second wavelength.

9. The light source of claim 2, wherein the light emitting device comprises a light emitting surface flush with the top surface of the optical barrier.

10. The light source of claim 1, wherein the optical barrier is not black.

11. The light source of claim 1, wherein the optical barrier is dyed.

12. The light source of claim 1, wherein optical barrier comprises pigments.

13. The light source of claim 1, wherein the a vol % of the pigments is from 0.1-2 vol % of the optical barrier.

14. The light source of claim 12, wherein the particles are luminescent particles.

15. The light source of claim 1, wherein the optical barrier is not in direct contact with the light emitting structure.

16. The light source of claim 1, wherein side walls of the one optical barrier extend in a vertical direction perpendicular to a horizontal direction, the optical barrier entirely horizontally surrounds the light emitting structure without horizontally surrounding the wavelength converting layer.

17. The light source of claim 1, further comprising a side coat between the optical barrier and light emitting structure.

18. A light source comprising:
a light emitting structure arranged to emit a light of a first wavelength;
an optical barrier disposed adjacent to the light emitting structure comprising a top surface, a bottom surface opposite the top surface, and side walls extending between the top surface and the bottom surface, the optical barrier comprising a black pigment and TiOₓ.

19. The light source of claim 18, wherein the optical barrier entirely horizontally surrounds the light emitting structure.

20. The light source of claim 18, further comprising a substrate upon which the light emitting structure and the optical barrier are disposed.
